(19) United States
(12) Patent Application Publication
(10) Pub. No.: US 2012/0193809 A1
(43) Pub. Date: Aug. 2, 2012

(54) INTEGRATED CIRCUIT DEVICE AND METHOD FOR PREPARING THE SAME

(75) Inventor: Jui Hsuan Chung, Xinshuang City (TW)

(73) Assignee: Nanya Technology Corp., Kueishan (TW)

(21) Appl. No.: 13/018,790

(22) Filed: Feb. 1, 2011

(51) Int. Cl. H01L 23/48; H01L 21/30

(52) U.S. Cl. 257/774; 438/459; 257/E23.011; 257/E21.482

(57) ABSTRACT

An integrated circuit device includes a bottom wafer having a first dielectric block and a first conductive block on the first dielectric block; at least one stacking wafer having a second dielectric block and at least one second conductive block on the second dielectric block, wherein the stacking wafers are bonded to the bottom wafer by an adhesive layer, and no bump pad is positioned between the bottom wafer and the stacking wafer; and a conductive via penetrating through the stacking wafer and into the bottom wafer in a substantially linear manner, wherein the conductive via is positioned within the first conductive block and the second conductive block.

### 1. TECHNICAL FIELD

The present invention relates to an integrated circuit device having stacking wafers with through silicon vias and a method for preparing the same. More particularly, the present invention relates to an integrated circuit device of stacked wafers and method for preparing the same by bonding wafers before the formation of the through silicon via without forming a bump pad between the bonded wafers or using solder.

### 2. BACKGROUND

Packaging technology for integrated circuit structures has continuously developed to meet the demand for miniaturization and mounting reliability. Recently, as the miniaturization and high functionality of electric and electronic products are required, various techniques have been disclosed in the art.

By using a stack of at least two chips, i.e., the so-called 3D package, in the case of a memory device, it is possible to produce a product having a memory capacity which is twice as large as that obtainable through other semiconductor integration processes. Also, a stack package provides advantages not only of an increase in memory capacity but also in regards to mounting density and mounting area utilization efficiency. Due to such advantages, research and development of stack package technology has accelerated.

As an example, a stack package with a through-silicon via (TSV) has been disclosed in the art. The stack package using a TSV has a structure in which the TSV is disposed in a chip so that chips are physically and electrically connected with each other through the TSV. Generally, a TSV is formed by etching a vertical via through a substrate and filling the via with a conductive material, such as copper. To increase the transmission speed and for high-density fabrication, the thickness of a semiconductor wafer comprising multiple integrated circuit structures each having the TSV needs to be reduced.

U.S. Pat. No. 7,683,459 discloses a hybrid bonding method for through silicon via based wafer stacking, in which patterned adhesive layers are provided to join adjacent wafers in the stack, while solder bonding is used to electrically connect the lower end of the via in the upper wafer to the bump pad on the upper end of the via in the lower wafer. However, the formation of the bump pad on the upper end of the via requires seeding, electroplating, photolithography and etching processes; therefore, the formation of the bump pad on the upper end of the via is very complicated and expensive.

### SUMMARY OF THE INVENTION

One aspect of the present invention is to provide an integrated circuit device of stacked wafers and method for preparing the same by bonding wafers prior to the formation of the through silicon via such that no bump pad is positioned between the stacking wafer and the bottom wafer; therefore, the issues of complicated processing and high cost can be resolved.

In one embodiment of the present invention, an integrated circuit device comprises a bottom wafer having a first dielectric block and a first conductive block on the first dielectric block; at least one stacking wafer having a second dielectric block and at least one second conductive block on the second dielectric block, wherein the stacking wafer is bonded to the bottom wafer by an adhesive layer, and no bump pad is positioned between the bottom wafer and the stacking wafer; and a conductive via penetrating through the stacking wafer and into the bottom wafer in a substantially linear manner, wherein the conductive via is positioned within the first conductive block and the second conductive block.

Another aspect of the present invention discloses a method for preparing an integrated circuit device comprising the steps of forming a bottom wafer having a first depression, a first dielectric block in the first depression and a first conductive block on the first dielectric block; forming at least one stacking wafer having a second depression, a second dielectric block in the second depression and at least one second conductive block on the second dielectric block; bonding the at least one stacking wafer to the bottom wafer by an adhesive layer, without forming a bump pad between the bottom wafer and the stacking wafer; performing an etching process to form a via hole penetrating through the stacking wafer and into the bottom wafer in a substantially linear manner, wherein the via hole is formed within the first conductive block and the second conductive block; and filling the via hole with conductive material to form a conductive via.

Compared to the technique disclosed in U.S. Pat. No. 7,683,459, which forms one bump pad for each wafer, the embodiment of the present invention forms the integrated circuit device by bonding wafers prior to the formation of the through silicon via that penetrates through the stacking wafer and not through the bottom wafer. Consequently, the embodiment of the present invention does not require that the bump pad be formed between the stacking wafer and the bottom wafer; therefore, the issues of complicated processing and high cost can be resolved.

In addition, the formation of the first conductive block and the second conductive block, serving as the seed/barrier layer of the through silicon via, are performed before the formation the via hole. In other words, the seed/barrier layer is formed in the depression with low aspect ratio, rather than in the via hole with high aspect ratio, and the problem of the formation of the seed/barrier layer inside the via hole with high aspect ratio is solved.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes as those of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIG. 1 and FIG. 2 are cross-sectional views of a silicon wafer in accordance with one embodiment of the present invention;

FIG. 3 is a cross-sectional view of the silicon wafer in accordance with one embodiment of the present invention;

FIG. 4 is a cross-sectional view of a bottom wafer in accordance with one embodiment of the present invention;

FIG. 5 is a cross-sectional view of a silicon wafer in accordance with one embodiment of the present invention;

FIG. 6 is a cross-sectional view of a stacking wafer in accordance with one embodiment of the present invention;

FIG. 7 is a cross-sectional view of the stacking wafer adhered to the bottom wafer in accordance with one embodiment of the present invention;

FIG. 8 is a cross-sectional view showing a via hole penetrating through the stacking wafer and into the bottom wafer in accordance with one embodiment of the present invention;

FIG. 9 is a cross-sectional view showing a conductive via formed in the via hole in accordance with one embodiment of the present invention;

FIG. 10 is a top view showing the integrated circuit device in accordance with one embodiment of the present invention;

FIG. 11 and FIG. 12 are cross-sectional views of a silicon wafer in accordance with one embodiment of the present invention;

FIG. 13 is a cross-sectional view of a bottom wafer in accordance with one embodiment of the present invention;

FIG. 14 is a cross-sectional view of a silicon wafer in accordance with one embodiment of the present invention;

FIG. 15 is a cross-sectional view of a stacking wafer in accordance with one embodiment of the present invention;

FIG. 16 is a cross-sectional view of the stacking wafer adhered to the bottom wafer in accordance with one embodiment of the present invention;

FIG. 17 is a cross-sectional view showing a via hole penetrating through the stacking wafer and into the bottom wafer in accordance with one embodiment of the present invention; and

FIG. 18 is a cross-sectional view showing a conductive via formed in the via hole in accordance with one embodiment of the present invention.

### DETAILED DESCRIPTION

To solve the problem of the technique disclosed in U.S. Pat. No. 7,683,459, forming one bump pad for each wafer, which is very complicated and expensive, the present disclosure proposes a method for forming the integrated circuit device by bonding wafers prior to the formation of the through silicon via that penetrates through the stacking wafers such that there is no need to form the bump pad between the stacking wafer and the bottom wafer, and the issues of complicated processing and high cost can be resolved.

After bonding the wafers, the formation of the through silicon via needs to form a through hole with high aspect ratio, a seeding/barrier layer in the through hole, and fill the through hole with conductive material by the plating process. To implement this technique, one key challenge needs to be addressed, i.e., the formation of the seed/barrier layer inside the through hole with high aspect ratio.

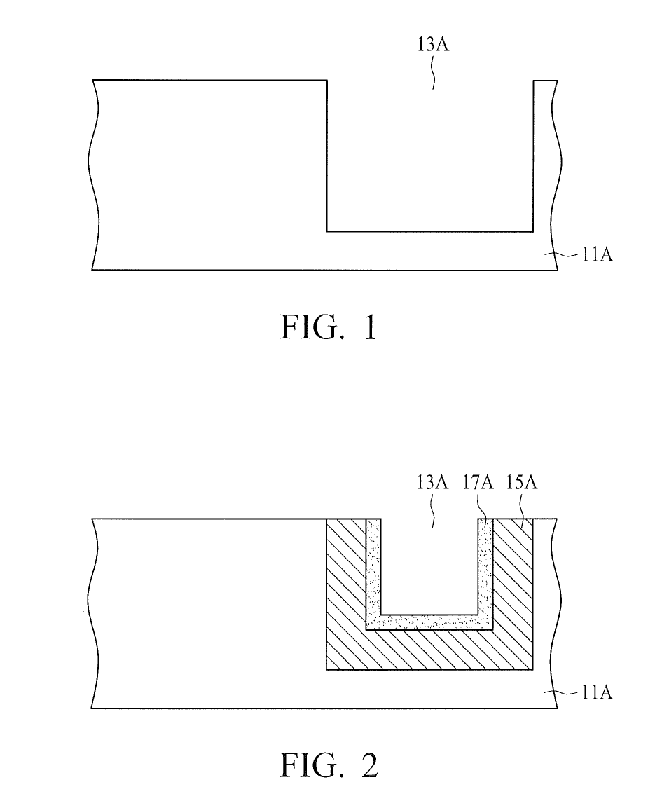

FIG. 1 to FIG. 10 are schematic diagrams showing a method for forming an integrated circuit device 100 in accordance with one embodiment of the present invention. FIG. 1 and FIG. 2 are cross-sectional views of a silicon wafer 11A in accordance with one embodiment of the present invention. In one embodiment of the present invention, fabrication processes are performed to form a depression 13A in the silicon wafer 11A. Subsequently, fabrication processes are performed to form a first dielectric block 15A in the depression 13A and a first conductive block 17A on the first dielectric block 15A, as shown in FIG. 2. In one embodiment of the present invention, the first conductive block 17A comprises a barrier layer and a seed layer, wherein the barrier layer may include titanium, and the seed layer may include copper.

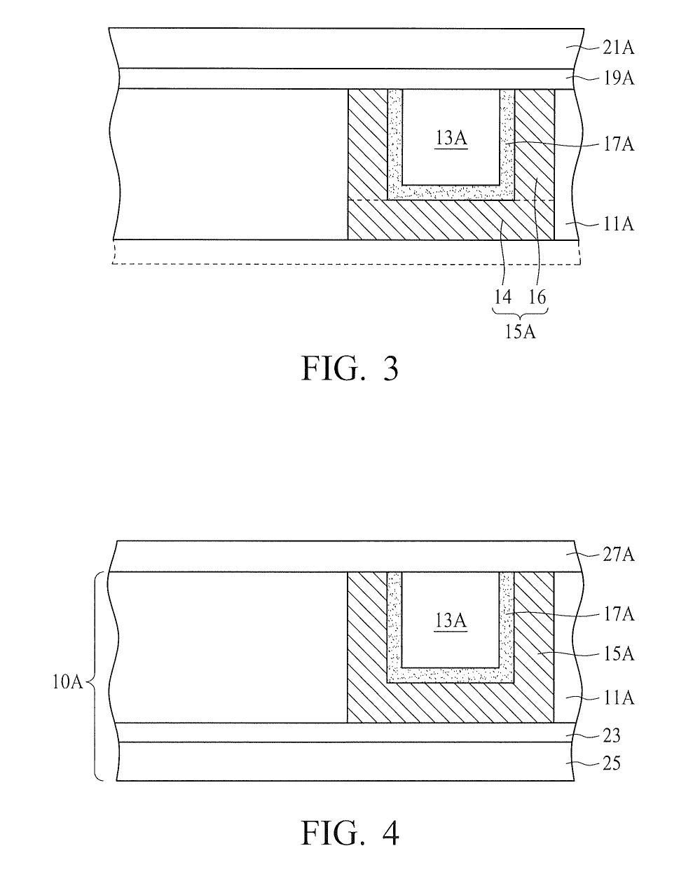

FIG. 3 is a cross-sectional view of the silicon wafer 11A in accordance with one embodiment of the present invention. In one embodiment of the present invention, a carrier 21A is adhered to the top side of the silicon wafer 11A via a glue layer 19A, and a thinning process such as the backside grinding process or CMP process is then performed to remove a portion of the silicon wafer 11A from the bottom side of the silicon wafer 11A. In one embodiment of the present invention, the thinning process is performed to remove a portion of the silicon wafer 11A from the bottom side of the silicon wafer 11A such that the bottom end of the first dielectric block 15A is exposed. Consequently, the first dielectric block 15A comprises a bottom portion 14 and an annular sidewall portion 16 on the bottom portion 14.

FIG. 4 is a cross-sectional view of a bottom wafer 10A in accordance with one embodiment of the present invention. In one embodiment of the present invention, a stiff substrate 25 is adhered to the bottom side of the silicon wafer 11A via a glue layer 23, and the carrier 21A and the glue layer 19A are then removed. Subsequently, an adhesive layer 27A is formed on the top side of the silicon wafer 11A to form the bottom wafer 10A. In one embodiment of the present invention, the adhesive layer 27A is patterned to define interconnecting channels (not shown in the drawings).

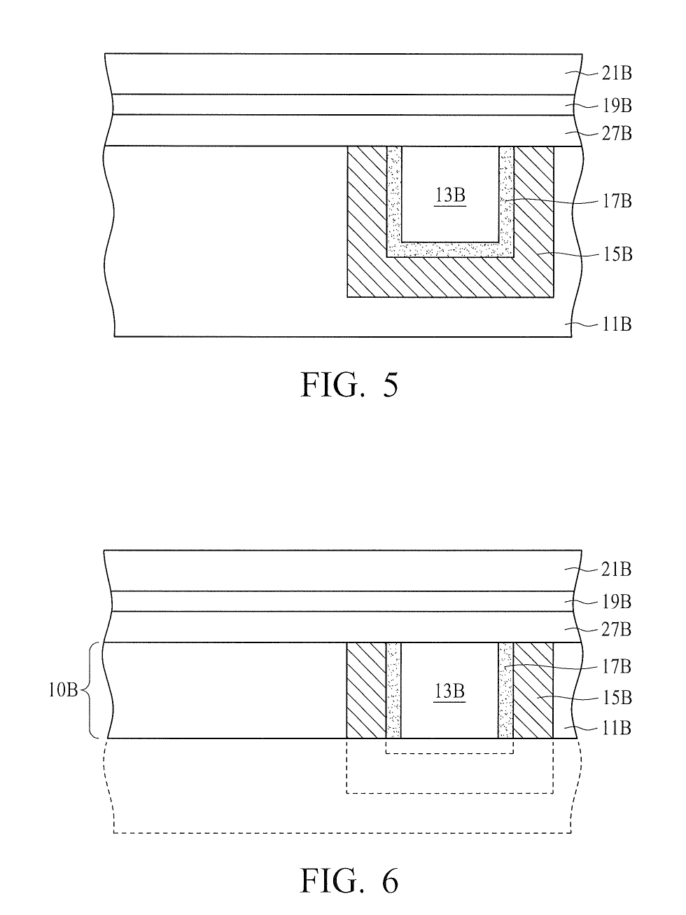

FIG. 5 is a cross-sectional view of a silicon wafer 11B in accordance with one embodiment of the present invention. In one embodiment of the present invention, the fabrication processes shown in FIG. 1 and FIG. 2 are performed again on another silicon wafer 11B to form a depression 13B, a second dielectric block 15B in the depression 13B and a second block 17B on the second dielectric block 15B. In one embodiment of the present invention, the second conductive block 17B comprises a barrier layer and a seed layer, wherein the barrier layer may include titanium, and the seed layer may include copper.

FIG. 6 is a cross-sectional view of a stacking wafer 10B in accordance with one embodiment of the present invention. In one embodiment of the present invention, an adhesive layer 27B is formed on the top side of the silicon wafer 11B, and a carrier 21B is adhered to the top side of the silicon wafer 11B via a glue layer 19B. Subsequently, a thinning process such as the backside grinding process or CMP process is then performed to remove a portion of the silicon wafer 11B from the bottom side of the silicon wafer 11B to form the stacking wafer 10B. In one embodiment of the present invention, the thinning process is performed to remove a portion of the silicon wafer 11B from the bottom side of the silicon wafer 11B such that the second dielectric block 15B and the depression 13B are exposed. Consequently, the second dielectric block 15B is annular.

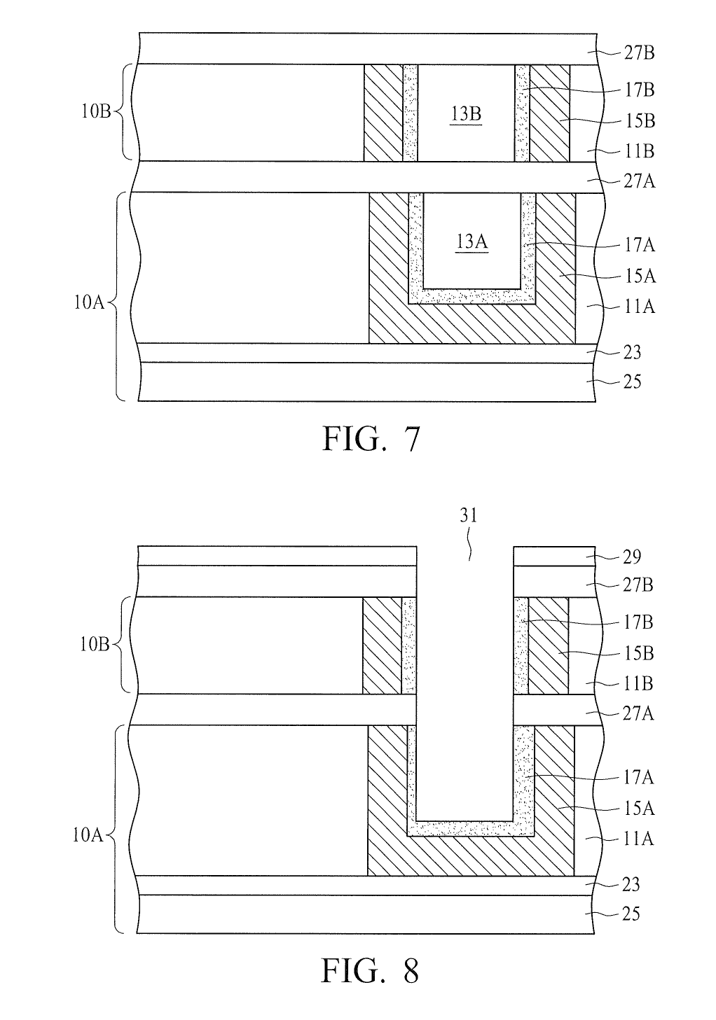

FIG. 7 is a cross-sectional view of the stacking wafer 10B adhered to the bottom wafer 10A in accordance with one embodiment of the present invention. In one embodiment of the present invention, the stacking wafer 10B is bonded to the bottom wafer 10A by the adhesive layer 27A without forming a bump pad between the bottom wafer 10A and the stacking wafer 10B, and the carrier 21B and the glue layer 19B are removed from the top side of the stacking wafer 10B. In one embodiment of the present invention, the intervening adhesive layer 27A is the only layer between the bottom wafer 10A and the stacking wafer 10B, i.e., the stacking wafer 10B is bonded to the bottom wafer 10A without using solder. In one embodiment of the present invention, another stacking wafer 10B can be adhered to the top side of the stacking wafer 10B by the same technique, and so on, i.e., one or more stacking wafers 10B can be adhered to the bottom wafer 10A. In one embodiment of the present invention, since there may be misalignment between the bottom wafer 10A and the stacking wafer 10B, the first conductive block 17A may not be aligned with the second conductive block 17B, and the first dielectric block 15A may not be aligned with the second dielectric block 15B.

FIG. 8 is a cross-sectional view showing a via hole 31 penetrating through the stacking wafer 10B and into the bottom wafer 10A in accordance with one embodiment of the present invention. In one embodiment of the present invention, a photolithographic process is then performed to form a mask layer 29 on the stacking wafer 10B, and a dry etching process using fluorine-containing etching gas is then performed to form at least one via hole 31 penetrating through the stacking wafer 10B and into the bottom wafer 10A in a substantially linear manner. In one embodiment of the present invention, the at least one via hole 31 is formed within the first conductive block 17A and the second conductive block 17B.

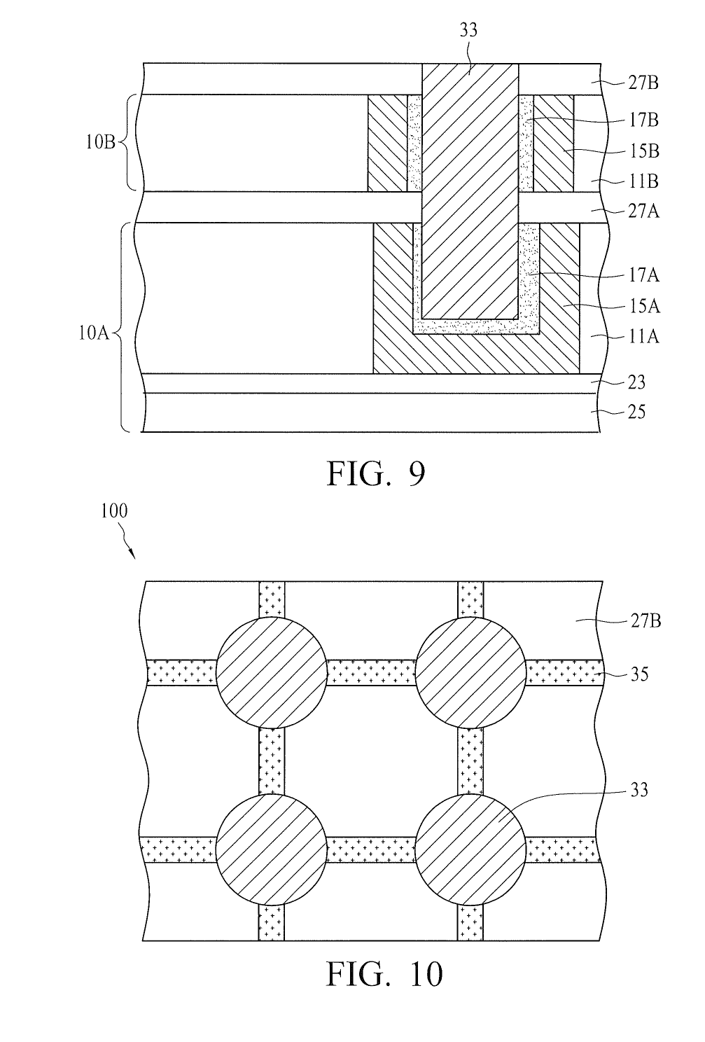

FIG. 9 is a cross-sectional view showing a conductive via 33 formed in the via hole 31 in accordance with one embodiment of the present invention. In one embodiment of the present invention, the mask layer 29 is stripped, and an electroplating process is then performed to form the conductive via (TSV) 33 by filling the via hole 31 with conductive material such as copper. In one embodiment of the present invention, the conductive via 33 penetrates through the stacking wafer 10B, and into the bottom wafer 10A. In one embodiment of the present invention, the conductive via 33 is formed within the first conductive block 17A and the second conductive block 17B.

FIG. 10 is a top view showing the integrated circuit device 100 in accordance with one embodiment of the present invention. In one embodiment of the present invention, the adhesive layer 27B is patterned to define interconnecting channels 35 to complete the integrated circuit device 100, wherein the interconnecting channels 35 are configured to electrically connect the conductive via 33 to the devices such as transistors of the stacking wafer 10B.

Compared to the technique disclosed in U.S. Pat. No. 7,683,459, which forms one bump pad for each wafer, the embodiment of the present invention forms the integrated circuit device 100 by bonding wafers 10A and 10B before the formation of the through silicon via 33 that penetrates through the stacking wafer 10B and not through the bottom wafer 10A. Consequently, the embodiment of the present invention does not require that a bump pad be formed between the stacking wafer 10B and the bottom wafer 10A; therefore, the issues of complicated processing and high cost can be solved.

In addition, the formation of the first conductive block 17A and the second conductive block 17B, both serving as the seed/barrier layer of the through silicon via 33, are performed before the formation the via hole 31. In other words, the seed/barrier layer is formed in the depressions 13A and 13B with low aspect ratio, rather than in the via hole 31 with high aspect ratio, and the problem of the formation of the seed/barrier layer inside the via hole 31 with high aspect ratio is solved.

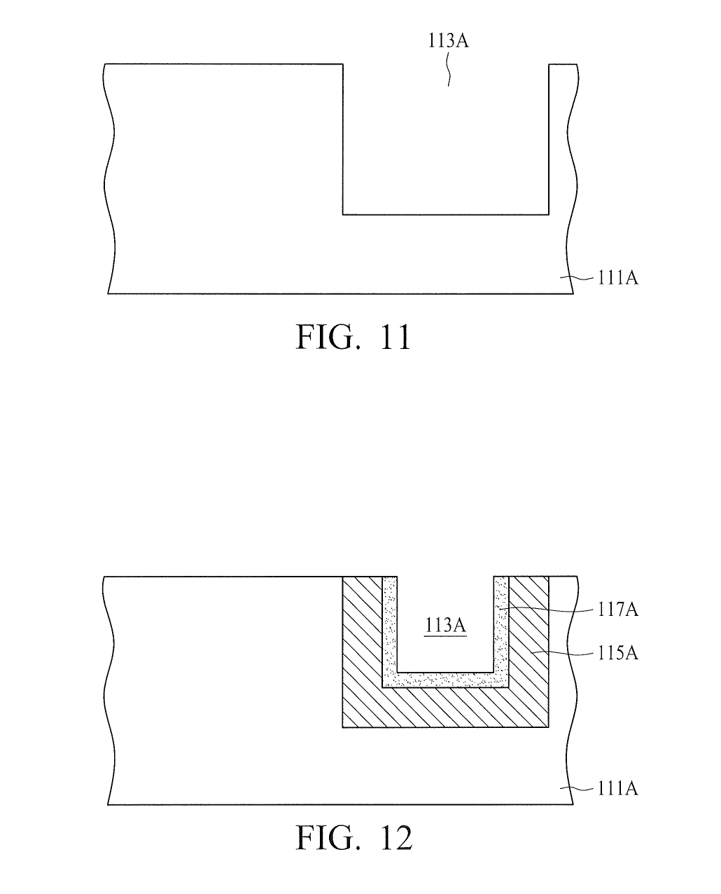

FIG. 11 to FIG. 18 are schematic diagrams showing a method for forming an integrated circuit device 200 in accordance with one embodiment of the present invention. FIG. 11 and FIG. 12 are cross-sectional views of a silicon wafer 111A in accordance with one embodiment of the present invention. In one embodiment of the present invention, fabrication processes are performed to form a depression 113A in the silicon wafer 111A. Subsequently, fabrication processes are performed to form a first dielectric block 115A in the depression 113A and a first conductive block 117A on the first dielectric block 115A, as shown in FIG. 12. In one embodiment of the present invention, the first conductive block 117A comprises a barrier layer and a seed layer, wherein the barrier layer may include titanium, and the seed layer may include copper.

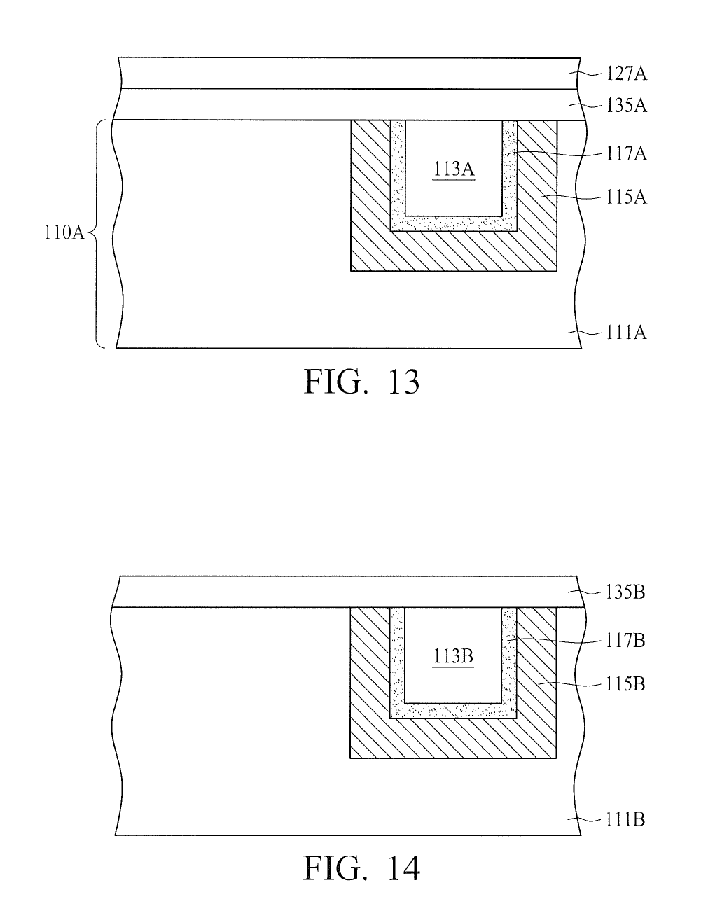

FIG. 13 is a cross-sectional view of a bottom wafer 110A in accordance with one embodiment of the present invention. In one embodiment of the present invention, a deposition process is performed to form an interconnect layer 135A on the top side of the silicon wafer 11A, and an adhesive layer 127A is then formed on the interconnect layer 135A to form the bottom wafer 110A.

FIG. 14 is a cross-sectional view of a silicon wafer 111B in accordance with one embodiment of the present invention. In one embodiment of the present invention, the fabrication processes shown in FIG. 11 to FIG. 13 are performed again on another silicon wafer 111B to form a depression 113B, a second dielectric block 115B in the depression 113B and a second block 117B on the second dielectric block 115B. In one embodiment of the present invention, the second conductive block 117B comprises a barrier layer and a seed layer, wherein the barrier layer may include titanium, and the seed layer may include copper. Subsequently, a deposition process is performed to form an interconnect layer 135B on the top side of the silicon wafer 11B.

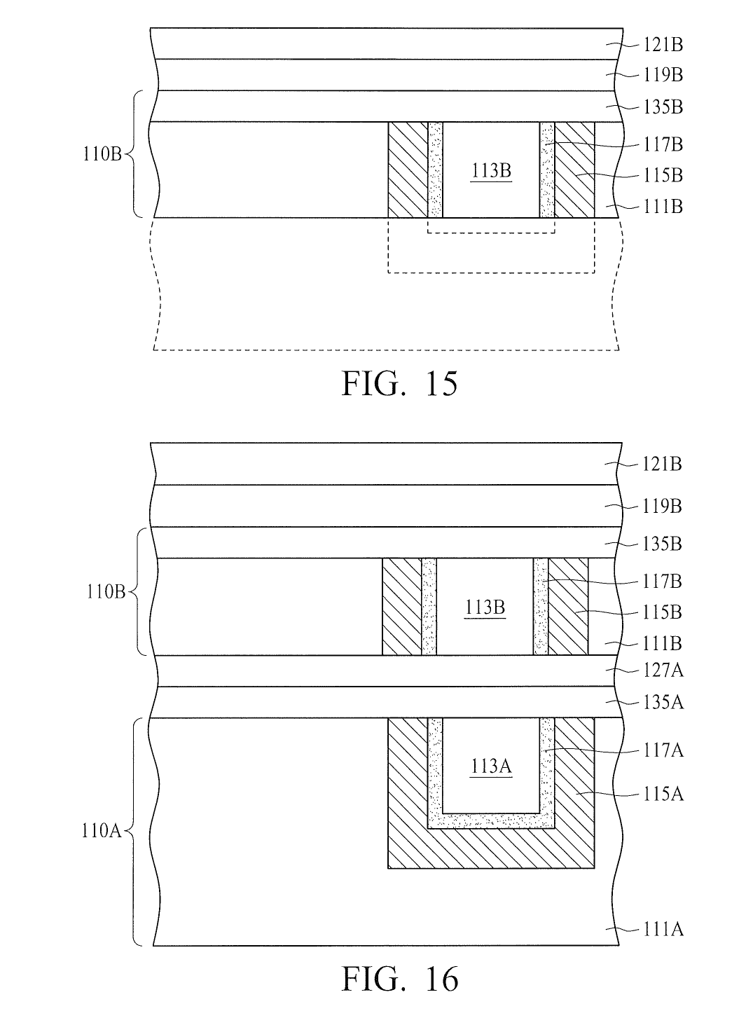

FIG. 15 is a cross-sectional view of a stacking wafer 10B in accordance with one embodiment of the present invention. In one embodiment of the present invention, a carrier 121B is adhered to the interconnect layer 135B via a glue layer 119B. Subsequently, a thinning process such as the backside grinding process or CMP process is then performed to remove a portion of the silicon wafer 111B from the bottom side of the silicon wafer 111B to form the stacking wafer 110B. In one embodiment of the present invention, the thinning process is performed to remove a portion of the silicon wafer 11aB from the bottom side of the silicon wafer 111B such that the second dielectric block 115B and the depression 113B are exposed. Consequently, the second dielectric block 115B is annular.

FIG. 16 is a cross-sectional view of the stacking wafer 110B adhered to the bottom wafer 110A in accordance with one embodiment of the present invention. In one embodiment of the present invention, the stacking wafer 10B is bonded to the bottom wafer 10A by the adhesive layer 127A without forming a bump pad between the bottom wafer 110A and the stacking wafer 110B. In one embodiment of the present invention, the adhesive layer 127A is the only layer between the bottom wafer 110A and the stacking wafer 110B, i.e., the stacking wafer 110B is bonded to the bottom wafer 110A without using solder. In one embodiment of the present invention, the carrier 121B and the glue layer 119B can be removed from the top side of the stacking wafer 110B, and another stacking wafer 110B can be adhered to the top side of the stacking wafer 110B by the same technique, and so on, i.e., one or more stacking wafers 110B can be adhered to the bottom wafer 110A.

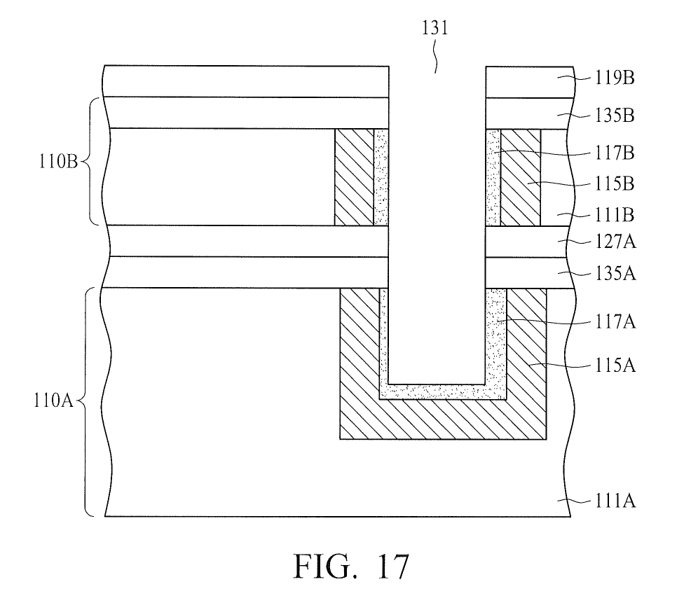

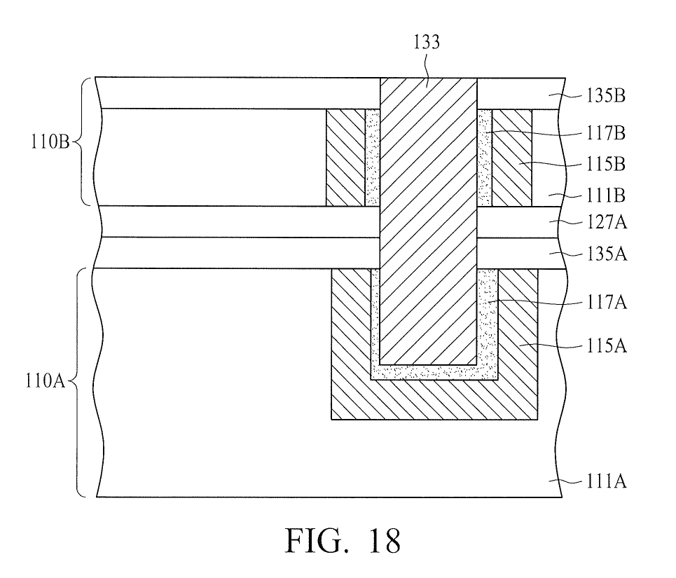

FIG. 17 is a cross-sectional view showing a via hole 131 penetrating through the stacking wafer 110B and into the bottom wafer 110A in accordance with one embodiment of the present invention. In one embodiment of the present invention, the carrier 121B and the glue layer 119B are removed from the top side of the stacking wafer 110B, a photolithographic process is then performed to form a mask layer 129 on the stacking wafer 110B, and a dry etching process using fluorine-containing etching gas is then performed to form at least one via hole 131 penetrating through the stacking wafer 110B and into the bottom wafer 110A in a substantially linear manner. In one embodiment of the present invention, the at least one via hole 131 is formed within the first conductive block 117A and the second conductive block 117B.

FIG. 18 is a cross-sectional view showing a conductive via 133 formed in the via hole 131 in accordance with one embodiment of the present invention. In one embodiment of the present invention, the mask layer 129 is stripped, and an electroplating process is then performed to form the conductive via (TSV) 133 by filling the via hole 131 with conductive material such as copper to complete the integrated circuit device 200. In one embodiment of the present invention, the conductive via 133 penetrates through the stacking wafer 110B and into the bottom wafer 110A. In one embodiment of the present invention, the conductive via 133 is formed within the first conductive block 117A and the second conductive block 117B.

Compared to the technique disclosed in U.S. Pat. No. 7,683,459, which forms one bump pad for each wafer, the embodiment of the present invention forms the integrated circuit device 200 by bonding wafers 110A and 110B before the formation of the through silicon via 133 that penetrates through the stacking wafer 10B and not through the bottom wafer 10A. Consequently, the embodiment of the present invention does not need to form a bump pad between the stacking wafer 110B and the bottom wafer 110A; therefore, the issues of complicated processing and high cost can be solved.

In addition, the formation of the first conductive block 117A and the second conductive block 117B, both serving as the seed/barrier layer of the through silicon via 133, are performed before the formation the via hole 129. In other words, the seed/barrier layer is formed in the depressions 113A and 113B with low aspect ratio, rather than in the via hole 129 with high aspect ratio, and the problem of the formation of the seed/barrier layer inside the via hole 129 with high aspect ratio is solved.

Although the present invention and its advantages have been described in detail, it should be understood that various changes, substitutions and alterations can be made hereto without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit device, comprising:
a bottom wafer having a first dielectric block and a first conductive block on the first dielectric block;
at least one stacking wafer having a second dielectric block and at least one second conductive block on the second dielectric block, wherein the stacking wafers are bonded to the bottom wafer by an adhesive layer, and no bump pad is positioned between the bottom wafer and the stacking wafer; and
a conductive via penetrating through the stacking wafer and into the bottom wafer in a substantially linear manner, wherein the conductive via is positioned within the first conductive block and the second conductive block.

2. The integrated circuit device of claim 1, wherein the first conductive block comprises a barrier layer and a seed layer.

3. The integrated circuit device of claim 1, wherein the first dielectric block comprises a bottom portion and an annular sidewall portion on the bottom portion.

4. The integrated circuit device of claim 1, wherein the second dielectric block is annular.

5. The integrated circuit device of claim 1, wherein the first conductive block comprises a bottom portion and an annular sidewall portion on the bottom portion.

6. The integrated circuit device of claim 1, wherein the second conductive block is annular.

7. The integrated circuit device of claim 1, wherein no solder is positioned between the bottom wafer and the stacking wafer.

8. The integrated circuit device of claim 1, wherein the bottom wafer further comprises an interconnect channel electrically connected to the conductive via.

9. The integrated circuit device of claim 1, wherein the first conductive block is not aligned with the second conductive block.

10. The integrated circuit device of claim 1, wherein the first dielectric block is not aligned with the second dielectric block.

11. The integrated circuit device of claim 1, wherein the bottom wafer further comprising an interconnect layer on a top side of the bottom wafer.

12. A method for preparing an integrated circuit device, comprising the steps of:
forming a bottom wafer having a first depression, a first dielectric block in the first depression and a first conductive block on the first dielectric block;
forming at least one stacking wafer having a second depression, a second dielectric block in the second depression and at least one second conductive block on the second dielectric block;
bonding the at least one stacking wafer to the bottom wafer by an adhesive layer, without forming a bump pad between the bottom wafer and the stacking wafer;
performing an etching process to form a via hole penetrating through the stacking wafer and into the bottom wafer in a substantially linear manner, wherein the via hole is formed within the first conductive block and the second conductive block; and
filling the via hole with conductive material to form a conductive via.

13. The method for preparing an integrated circuit device of claim 12, wherein the forming of the at least one stacking wafer comprises a step of performing a thinning process to remove a portion of the stacking wafer from a bottom side of the stacking wafer.

14. The method for preparing an integrated circuit device of claim 13, wherein the thinning process exposes the second dielectric block.

15. The method for preparing an integrated circuit device of claim 13, wherein the thinning process exposes the second depression.

16. The method for preparing an integrated circuit device of claim 12, wherein the forming of the bottom wafer comprises a step of performing a thinning process to remove a portion of the bottom wafer from a bottom side of the bottom wafer

17. The method for preparing an integrated circuit device of claim 16, wherein the thinning process exposes the first dielectric block.

18. The method for preparing an integrated circuit device of claim 12, wherein the via hole is formed without penetrating through the bottom wafer.

19. The method for preparing an integrated circuit device of claim 12, wherein the bonding of the at least one stacking wafer to the bottom wafer is performed without using solder between the bottom wafer and the stacking wafer.

20. The method for preparing an integrated circuit device of claim 12, further comprising a step of forming an interconnect channel electrically connected to the conductive via.
